(19) United States
(12) Patent Application Publication
(10) Pub. No.: US 2025/0086054 A1
(43) Pub. Date: Mar. 13, 2025

(54) SYSTEMS AND METHODS FOR MEMORY RECOVERY USING SECONDARY MEMORY

(71) Applicant: Samsung Electronics Co., Ltd., Suwon-si (KR)

(72) Inventors: Changhee Jung, Lafayette, IN (US); Yang Seok Ki, Palo Alto, CA (US)

(21) Appl. No.: 18/511,224

(22) Filed: Nov. 16, 2023

Related U.S. Application Data
(60) Provisional application No. 63/537,416, filed on Sep. 8, 2023.

(51) Int. Cl. G06F 11/10; G06F 13/16

(52) U.S. Cl. CPC G06F 11/1068; G06F 11/104; G06F 13/1668

(57) ABSTRACT

Provided is a method for memory recovery, the method including detecting, by a first memory controller, an error associated with a primary memory, receiving, by the first memory controller, information including a recovery code from an interface, and modifying, by the first memory controller, the error on the primary memory based on the information.

### CROSS-REFERENCE TO RELATED APPLICATION(S)

This application claims priority to, and benefit of, U.S. Provisional Application Ser. No. 63/537,416, filed on Sep. 8, 2023, entitled “ENHANCED MEMORY RECOVERY USING SECONDARY MEMORY,” the entire content of which is incorporated herein by reference.

### FIELD

Aspects of some embodiments of the present disclosure relate to systems and methods for memory recovery (e.g., data recovery).

### BACKGROUND

In the field of computers, a computing system may include a host and one or more memory devices coupled to (e.g., communicatively coupled to) the host. Such computing systems have become increasingly popular, in part, for allowing many different users to share the computing resources of the system. Memory requirements have increased over time as the number of users of such systems and the number and complexity of applications running on such systems have increased.

The present background section is intended to provide context only, and the disclosure of any embodiment or concept in this section does not constitute an admission that said embodiment or concept is prior art.

### SUMMARY

Aspects of some embodiments of the present disclosure are directed to computing systems and provide improvements to memory recovery for data reliability.

According to some embodiments of the present disclosure, there is provided a method for memory recovery, the method including detecting, by a first memory controller, an error associated with a primary memory, receiving, by the first memory controller, information including a recovery code from an interface, and modifying, by the first memory controller, the error on the primary memory based on the information.

The interface may be communicatively coupled to a secondary memory storing the recovery code.

The method may further include generating, by the first memory controller, the recovery code, and sending the recovery code to the secondary memory via the interface.

The sending the recovery code via the interface may be in accordance with a cache-coherent protocol.

The method may further include storing data associated with an application in the primary memory, and storing the recovery code in the secondary memory.

The secondary memory may be external to the primary memory.

The first memory controller may be communicatively coupled, via a data path, to a second memory controller, and the second memory controller may convert the recovery code into a format for sending from the interface.

The primary memory may include volatile memory.

The primary memory may include parity information, and the first memory controller may detect the error based on the parity information.

The recovery code may include at least one of a single-bit error correction, double-bit error detection (SECDED) code, or a triple-bit error correction, quadruple-bit error detection (TECQED) code.

The primary memory may include a memory module.

The primary memory may include an error correction code (ECC) memory including a location for processing detection and/or correction codes, and the method may further include generating, by the first memory controller, an error detection code and writing the error detection code to the location for processing detection and/or correction codes.

The primary memory may include one or more volatile-memory-based chips including a parity space, and the method may further include generating, by the first memory controller, an error detection code and writing the error detection code to the parity space.

The first memory controller may read at least a data associated with an application and an error detection code from the primary memory.

The receiving the information from the interface may be associated with a higher latency than receiving the information from the primary memory.

According to some other embodiments of the present disclosure, there is provided a device, including a primary memory, a first memory controller to generate a recovery code and communicatively coupled to the primary memory, and a second memory controller to convert the recovery code to a format for sending from an interconnection protocol.

The first memory controller may receive information including the recovery code from the second memory controller, and may modify an error on the primary memory based on the information.

The primary memory may include volatile memory.

The primary memory may include one or more volatile-memory-based chips including at least one of a parity space or a location for processing detection and/or correction codes.

According to some other embodiments of the present disclosure, there is provided a device including an interface to receive a request for information including a recovery code, and a secondary memory including the recovery code and being communicatively coupled to the interface to send the recovery code from the device.

### BRIEF DESCRIPTION OF THE DRAWINGS

Non-limiting and non-exhaustive embodiments of the present disclosure are described with reference to the following figures, wherein like reference numerals refer to like parts throughout the various views unless otherwise specified.

FIG. 1 is a system diagram depicting a system for memory recovery, according to some embodiments of the present disclosure.

FIG. 2 is a flowchart depicting example operations of a method for performing write operations in the system for memory recovery, according to some embodiments of the present disclosure.

FIG. 3 is a flowchart depicting example operations of a method for performing read operations in the system for memory recovery, according to some embodiments of the present disclosure.

FIG. 4 is a flowchart depicting example operations of a method for memory recovery, according to some embodiments of the present disclosure.

Corresponding reference characters indicate corresponding components throughout the several views of the drawings. Skilled artisans will appreciate that elements in the figures are illustrated for simplicity and clarity, and have not necessarily been drawn to scale. For example, the dimensions of some of the elements, layers, and regions in the figures may be exaggerated relative to other elements, layers, and regions to help to improve clarity and understanding of various embodiments. Also, common but well-understood elements and parts not related to the description of the embodiments might not be shown to facilitate a less obstructed view of these various embodiments and to make the description clear.

### DETAILED DESCRIPTION

Aspects of the present disclosure and methods of accomplishing the same may be understood more readily by reference to the detailed description of one or more embodiments and the accompanying drawings. Hereinafter, embodiments will be described in more detail with reference to the accompanying drawings. The described embodiments, however, may be embodied in various different forms, and should not be construed as being limited to only the illustrated embodiments herein. Rather, these embodiments are provided as examples so that this disclosure will be thorough and complete, and will fully convey aspects of the present disclosure to those skilled in the art. Accordingly, description of processes, elements, and techniques that are not necessary to those having ordinary skill in the art for a complete understanding of the aspects and features of the present disclosure may be omitted.

Unless otherwise noted, like reference numerals, characters, or combinations thereof denote like elements throughout the attached drawings and the written description, and thus, descriptions thereof will not be repeated. Skilled artisans will appreciate that elements in the figures are illustrated for simplicity and clarity, and have not necessarily been drawn to scale. For example, the dimensions of some of the elements, layers, and regions in the figures may be exaggerated relative to other elements, layers, and regions to help to improve clarity and understanding of various embodiments. Also, common but well-understood elements and parts not related to the description of the embodiments might not be shown to facilitate a less obstructed view of these various embodiments and to make the description clear.

In the detailed description, for the purposes of explanation, numerous specific details are set forth to provide a thorough understanding of various embodiments. It is apparent, however, that various embodiments may be practiced without these specific details or with one or more equivalent arrangements.

It will be understood that, although the terms “zeroth,” “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or component is referred to as being “on,” “connected to,” or “coupled to” another element or component, it can be directly on, connected to, or coupled to the other element or component, or one or more intervening elements or components may be present. However, “directly connected/directly coupled” refers to one component directly connecting or coupling another component without an intermediate component. Meanwhile, other expressions describing relationships between components such as “between,” “immediately between” or “adjacent to” and “directly adjacent to” may be construed similarly. In addition, it will also be understood that when an element or component is referred to as being “between” two elements or components, it can be the only element or component between the two elements or components, or one or more intervening elements or components may also be present.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, each of the terms “or” and “and/or” includes any and all combinations of one or more of the associated listed items. For example, the expression “A and/or B” denotes A, B, or A and B.

For the purposes of this disclosure, expressions such as “at least one of,” when preceding a list of elements, modify the entire list of elements and do not modify the individual elements of the list. For example, “at least one of X, Y, or Z,” “at least one of X, Y, and Z,” and “at least one selected from the group consisting of X, Y, and Z” may be construed as X only, Y only, Z only, or any combination of two or more of X, Y, and Z, such as, for instance, XYZ, XYY, YZ, and ZZ.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

When one or more embodiments may be implemented differently, a specific process order may be performed differently from the described order. For example, two consecutively described processes may be performed substantially at the same time or performed in an order opposite to the described order.

Any of the components or any combination of the components described (e.g., in any system diagrams included herein) may be used to perform one or more of the operations of any flow chart included herein. Further, (i) the operations are merely examples, and may involve various additional operations not explicitly covered, and (ii) the temporal order of the operations may be varied.

The electronic or electric devices and/or any other relevant devices or components according to embodiments of the present disclosure described herein may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the embodiments of the present disclosure.

Any of the functionalities described herein, including any of the functionalities that may be implemented with a host, a device, and/or the like or a combination thereof, may be implemented with hardware, software, firmware, or any combination thereof including, for example, hardware and/or software combinational logic, sequential logic, timers, counters, registers, state machines, volatile memories such as dynamic RAM (DRAM) and/or static RAM (SRAM), nonvolatile memory including flash memory, persistent memory such as cross-gridded nonvolatile memory, memory with bulk resistance change, phase change memory (PCM), and/or the like and/or any combination thereof, complex programmable logic devices (CPLDs), field programmable gate arrays (FPGAs), application-specific ICs (ASICs), central processing units (CPUs) including complex instruction set computer (CISC) processors and/or reduced instruction set computer (RISC) processors, graphics processing units (GPUs), neural processing units (NPUs), tensor processing units (TPUs), data processing units (DPUs), and/or the like, executing instructions stored in any type of memory. In some embodiments, one or more components may be implemented as a system-on-a-chip (SoC).

Any of the computational devices disclosed herein may be implemented in any form factor, such as 3.5 inch, 2.5 inch, 1.8 inch, M.2, Enterprise and Data Center Standard Form Factor (EDSFF), NF1, and/or the like, using any connector configuration such as Serial Advanced Technology Attachment (SATA), Small Computer System Interface (SCSI), Serial Attached SCSI (SAS), U.2, and/or the like. Any of the computational devices disclosed herein may be implemented entirely or partially with, and/or used in connection with, a server chassis, server rack, data room, data center, edge data center, mobile edge data center, and/or any combinations thereof.

Any of the devices disclosed herein that may be implemented as storage devices may be implemented with any type of nonvolatile storage media based on solid-state media, magnetic media, optical media, and/or the like. For example, in some embodiments, a storage device (e.g., a computational storage device) may be implemented as a solid-state drive (SSD) based on not-AND (NAND) flash memory, persistent memory such as cross-gridded nonvolatile memory, memory with bulk resistance change, PCM, and/or the like, or any combination thereof.

Any of the communication connections and/or communication interfaces disclosed herein may be implemented with one or more interconnects, one or more networks, a network of networks (e.g., the Internet), and/or the like, or a combination thereof, using any type of interface and/or protocol. Examples include Peripheral Component Interconnect Express (PCIe), non-volatile memory express (NVMe), NVMe-over-fabric (NVMe-oF), Ethernet, Transmission Control Protocol/Internet Protocol (TCP/IP), Direct Memory Access (DMA) Remote DMA (RDMA), RDMA over Converged Ethernet (ROCE), FibreChannel, InfiniBand, SATA, SCSI, SAS, Internet Wide Area RDMA Protocol (iWARP), and/or a coherent protocol, such as Compute Express Link (CXL), CXL.mem, CXL.cache, CXL.IO and/or the like, Gen-Z, Open Coherent Accelerator Processor Interface (OpenCAPI), Cache Coherent Interconnect for Accelerators (CCIX), and/or the like, Advanced extensible Interface (AXI), any generation of wireless network including 2G, 3G, 4G, 5G, 6G, and/or the like, any generation of Wi-Fi, Bluetooth, near-field communication (NFC), and/or the like, or any combination thereof.

In some embodiments, a software stack may include a communication layer that may implement one or more communication interfaces, protocols, and/or the like such as PCIe, NVMe, CXL, Ethernet, NVMe-oF, TCP/IP, and/or the like, to enable a host and/or an application running on the host to communicate with a computational device or a storage device.

Unless otherwise defined, all terms (including technical and scientific terms) used herein have the same meaning as commonly understood by one of ordinary skill in the art to which the present inventive concept belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

As mentioned above, in the field of computers, a computing system may include a host and one or more memory devices communicatively coupled to the host. The memory devices may include memory modules with non-volatile memory, such as DRAM. For example, the memory modules may include dual in-line memory modules (DIMMs). The memory devices may also include storage devices with both memory capabilities and storage capabilities, such as SSDs. For example, some of the storage devices may be capable of performing memory functions via a cache-coherent protocol, such as CXL. Such storage devices may be capable of performing storage functions via non-volatile memory.

Data reliability issues (e.g., data errors) may occur in the memory devices due to soft errors, wherein a portion of data used by one or more applications running on the host becomes inaccurate. For example, the portion of data may become corrupted due to one or more bit flips. In some systems, error correction code (ECC) memory may be used to provide computing systems with the ability to detect and correct data errors in memory. Although ECC memory may be able to improve memory reliability of a computing system, ECC memory may have disadvantages compared to non-ECC memory (e.g., memory that is not capable of correcting data errors in memory). For example, non-ECC memory may be less expensive and may be faster than ECC memory.

Aspects of some embodiments of the present disclosure allow for enhanced memory reliability from both non-ECC memory modules and ECC memory modules by separating detection codes and correction codes respectively into a target memory and a secondary memory. Aspects of some embodiments of the present disclosure may be used to free up memory space (e.g., to make more memory space available) in the target memory and to allow for flexibility in providing enhanced error correction capabilities to suit a variety of applications. In some embodiments, non-ECC memory modules may be enabled to detect and correct data errors. For example, a non-ECC memory module may be enabled to detect and correct single-bit data errors, instead of not being able to correct any errors. In some embodiments, ECC memory modules may be enabled to have enhanced error detection and/or correction capabilities. For example, a single-bit error correction, double-bit error detection (SECDED) memory module may be enabled to detect and correct up to three-bit errors, instead of only detecting up to two-bit errors and only correcting one-bit errors.

In modern computer architecture, ECC may be used to protect an entire memory hierarchy, from a level-one (L1) cache to a main memory, against soft errors. ECC may be used for low-power cores such as Advanced RISC Machine (ARM) due to their use in mission-critical embedded systems, such as cyber-physical systems, unmanned aerial vehicles, and self-driving cars, where errors may be detected and corrected for safety reasons. However, ECC may have disadvantages. For example, ECC may be computationally expensive in that ECC-protected caches and memory may increase a critical path of data access and may also lead to clock frequency reduction. The L1 cache may be one of the most timing-critical components within a processor pipeline. However, building an L1 data cache with ECC may make it difficult for such systems to be designed to meet a core clock requirement (e.g., a two-cycle core clock requirement). ECC memory may also cost more than non-ECC memory.

In some systems, ECC memory (e.g., ECC DIMMs) may cause a performance degradation (e.g., about a two-percent performance degradation) compared non-ECC DIMMs. Because ECC DIMMs are made with less timing margin than non-ECC DIMMs, it may be more challenging to increase the clock speed with ECC DIMMs than with non-ECC DIMMs. Thus, systems using non-ECC DIMMs may take advantage of faster clock frequencies than ECC DIMMs.

Moreover, ECC memory may be more expensive (e.g., significantly more expensive) than corresponding non-ECC memory, with other component configurations being the same. Accordingly, non-ECC memory may be desirable for building a larger and faster memory than may be possible with ECC memory.

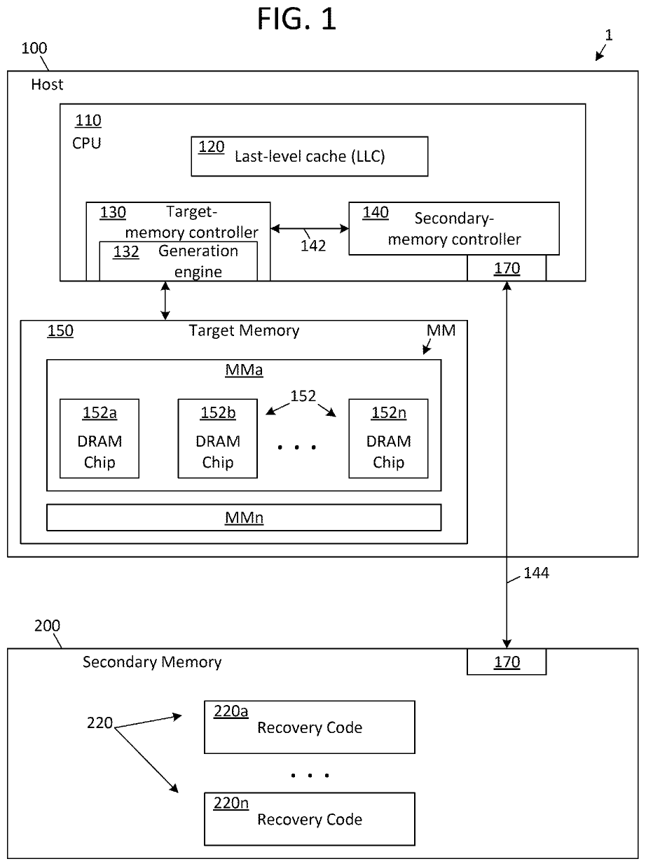

FIG. 1 is a system diagram depicting a system for memory recovery, according to some embodiments of the present disclosure.

Referring to FIG. 1, a system 1 may include a host 100, a target memory 150 (e.g., a primary memory), and a secondary memory 200. The target memory 150 and the secondary memory 200 may correspond to separate memory devices, such that the secondary memory 200 is external to and remote from the target memory 150. The host 100 may include a central-processing unit (CPU) 110. The CPU 110 may include a last-level cache (LLC) 120. A target-memory controller 130 (e.g., first memory controller, including a DRAM controller) may run on the CPU 110. The target-memory controller 130 may work together with the LLC 120 to manage and/or perform operations associated with writing data to the target memory 150 and reading the data from the target memory 150. The data may be associated with applications running on the host 100. The target-memory controller 130 may also manage and/or perform operations associated with data recovery. For example, the target-memory controller 130 may include a generation engine 132 for generating reliability metadata. The reliability metadata may include error detection codes and recovery codes (e.g., ECCs). The target-memory controller 130 may generate and store error detection codes in the target memory 150. The target-memory controller 130 may generate and store recovery codes in the secondary memory 200.

The target memory 150 may include memory modules MM. The memory modules MM may include DRAM. For example, the memory modules MM may include DIMMs. The memory modules MM may include one or more DRAM chips 152 (e.g., volatile-memory-based chips, including a first DRAM chip 152a through an n-th DRAM chip 152n). In some embodiments, the memory modules MM of the target memory 150 may be non-ECC memory modules. In such embodiments, the target memory 150 may include a parity space (or parity spaces). For example, non-ECC memory modules may be associated with reliability metadata such as parity information (e.g., parity metadata), for detecting memory errors. In some embodiments, parity may be maintained per DRAM chip 152. For example, parity bits may be stored (e.g., cached) in each DRAM chip 152 to maintain parity per DRAM chip 152. In some embodiments, parity may be maintained per memory module MM. For example, one parity bit may be cached in the target-memory controller 130 to maintain parity per memory module MM. In some embodiments, a non-ECC memory module may include eight DRAM chips 152.

In some embodiments, the DIMMs may be ECC memory modules. In such embodiments, one or more DRAM chips 152 may include an ECC space (e.g., a location for processing detection and/or correction codes). For example, in some embodiments, an ECC memory module may include an additional DRAM chip 152 (e.g., a ninth DRAM chip 152) including the reliability metadata (e.g., the ECC) for error detection and error correction. The ECC may be stronger reliability metadata than parity information.

In some embodiments, the target-memory controller 130 may be communicatively coupled to the secondary memory 200 via an interconnection interface 170 of the host 100. For example, the secondary memory 270 may be a low-tier memory. The secondary memory 270 may be considered low tier because it is farther away from the CPU 110 than the target memory 150. Accordingly, there may be higher latencies associated with the CPU accessing data (or metadata) from the secondary memory 200 via the interconnection interface 170 than with the CPU 110 accessing data (or metadata) from the target memory 150. The interconnection interface 170 may be coupled to the secondary memory 200 via an interconnection 144. The interconnection 144 may be capable of transferring data and/or metadata between the host 100 and the secondary memory 200 via an interconnection protocol. In some embodiments, the interconnection protocol may be a cache-coherent protocol. For example, the interconnection 144 may include a CXL interconnection. In such embodiments, a secondary-memory controller 140 (e.g., a second memory controller, including a CXL root port) may be provided between the target-memory controller 130 and the secondary memory 200. In some embodiments, the target-memory controller 130 may include the secondary-memory controller 140, such that operations and functions associated with the secondary-memory controller 140 herein may also be associated with the target-memory controller 130. The target-memory controller 130 may be connected to the secondary-memory controller 140 via a data path 142. The secondary-memory controller 140 may manage and/or perform operations associated with writing reliability metadata to, and reading reliability metadata from, the secondary memory 200. For example, the secondary-memory controller 140 may convey a recovery code 220, which is generated by the target-memory controller 130, to the secondary memory using a format that is suitable for the underlying interconnection protocol. In some embodiments, the target-memory controller 130 may cause recovery codes 220 to be sent from the host 100 to the secondary memory 200. The secondary memory 200 may receive the recovery codes 220 (e.g., a first recovery code 220a through an n-th recovery code 220n) from the target-memory controller 130 at an interconnection interface 170 of the secondary memory 200. In some embodiments, a first recovery code 220a may be associated with a first memory module MMa and an n-th recovery code 220n may be associated with an n-th memory module MMn.

As discussed above, in some embodiments, the target memory 150 may include non-ECC memory modules. In such embodiments, parity-based memory modules may be used for detection purposes while the target-memory controller 130 may generate reliability metadata (e.g., recovery codes) for each write (e.g., for each eight-byte write) to the target memory 150. Accordingly, a non-ECC memory module having no error-correction capabilities may be enabled for error correction. For example, the target-memory controller 130 may generate error detection codes and may store them (e.g., cache them) in the parity space of the non-ECC memory modules. The target-memory controller 130 may use the error detection codes to detect data errors based on reading data from the target memory 150. The target-memory controller 130 may also generate recovery codes (e.g., SECDED codes) for each write to the target memory 150. The target-memory controller 130 may send the recovery codes (e.g., the SECDED codes) to the secondary memory 200 for use (e.g., for later retrieval and use) in correcting any detected single-bit errors. The target-memory controller 130 may send the recovery codes to the secondary memory 200 synchronously or asynchronously.

In some embodiments, the target memory 150 may include a CXL-based memory expander with parity-based DIMMs. If an in-DIMM parity logic detects a data error (e.g., a one-bit error) that frequently causes a program (e.g., an application) to crash, due to an inability to correct the data error, the secondary-memory controller 140 (e.g., a CXL controller) may consult a corresponding SECDED code (e.g., a SECDED-ECC) available in the secondary memory 200. In some embodiments, the secondary memory 200 may include a CXL-based SSD array. In such embodiments, the target-memory controller 130 may correct the error, rather than crashing the program (e.g., rather than crashing the application associated with the data error).

It should be understood that providing error recovery via the secondary memory 200 may be applied to any DIMMs (e.g., a local DRAM connected to sockets of the CPU 110) and is not limited only to DIMMs of CXL-based memory expanders (or memory pools).

As discussed above, in some embodiments, the target memory 150 may include ECC memory modules. In such embodiments, a SECDED memory module may be equipped for triple-bit error detection and correction without the logic costs and performance penalties of triple error correction, quadruple error detection (TECQED) codes in the memory modules.

For example, a SECDED memory module of the target memory 150 may be used by the host 100 solely for error detection purposes to detect up to 3-bit errors (e.g., 1-bit to 3-bit errors), instead of only two-bit errors. In such embodiments, the target-memory controller 130 may generate TECQED code for each write (e.g., for each eight-byte write) to the target memory 150. The target-memory controller 130 may send the TECQED code to the secondary memory 200. Accordingly, an ECC memory module may have its error detection and correction capabilities enhanced. If any 1-to-3-bit error is detected in the SECDED memory module, the secondary-memory controller 140 may consult the corresponding TECQED code in the secondary memory 200 and correct the error in the target memory 150 (e.g., in the SECDED memory module location).

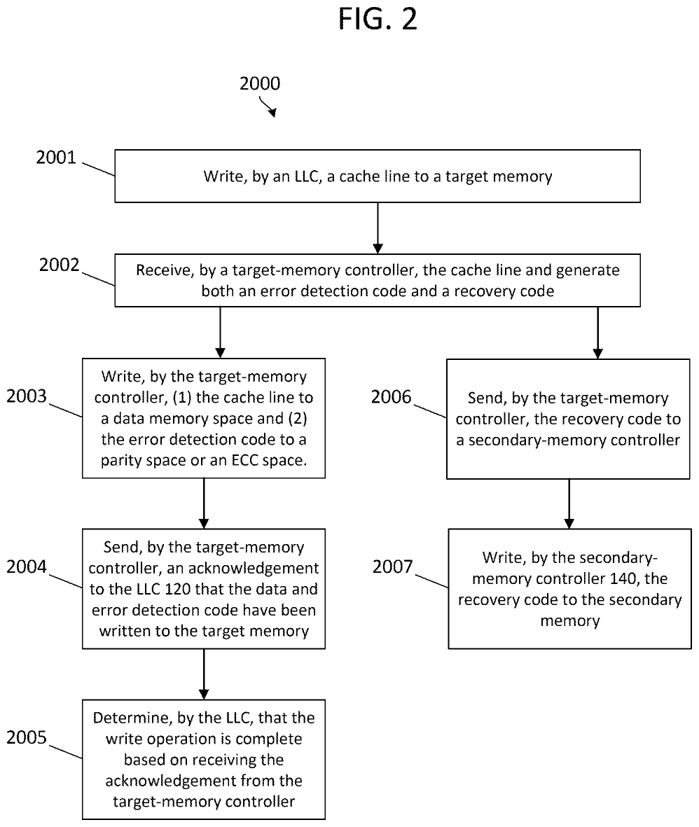

FIG. 2 is a flowchart depicting example operations of a method for performing write operations in the system for memory recovery, according to some embodiments of the present disclosure.

Referring to FIG. 2, a method 2000 for performing write operations in the system 1 of FIG. 1 may include the following operations. The LLC 120 may write a cache line (e.g., a 64-byte cache line), associated with data, to the target memory 150 (operation 2001). The target-memory controller 130 may receive the cache line and may generate both an error detection code and a recovery code 220 (e.g., an ECC) (operation 2002). The target-memory controller 130 may write the cache line to a data memory space in the target memory 150 and may write the error detection code to a parity space (in a non-ECC memory module) in the target memory 150 or to an ECC space (in an ECC memory module) in the target memory 150 (operation 2003). The target-memory controller 130 may send an acknowledgement to the LLC 120 that the data and error detection code have been written to the target memory 150 (operation 2004). The LLC 120 may determine that the write operation is complete based on receiving the acknowledgement from the target-memory controller 130 (operation 2005). In parallel with operations 2003, 2004, and/or 2005 (e.g., before, after, or concurrently with operations 2003, 2004, and/or 2005), the target-memory controller 130 may send the recovery code 220 to the secondary-memory controller 140 (operation 2006). The secondary-memory controller 140 may write the recovery code 220 to a memory space (e.g., a reserved memory space) in the secondary memory 200 for later use, by the target-memory controller, in memory recovery (e.g., for use based on detecting a memory error) (operation 2007).

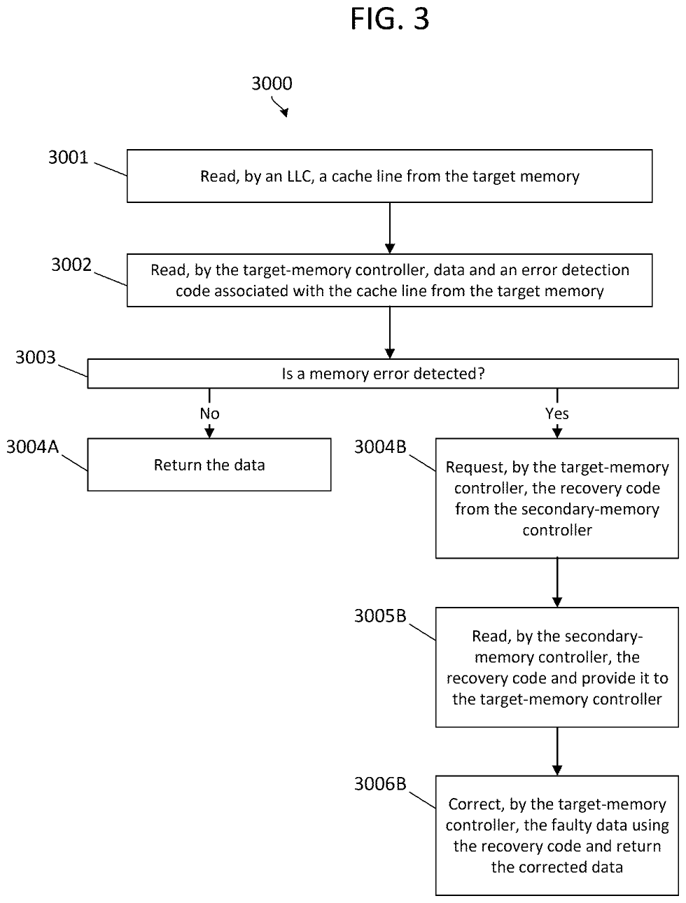

FIG. 3 is a flowchart depicting example operations of a method for performing read operations in the system for memory recovery, according to some embodiments of the present disclosure.

Referring to FIG. 3, a method 3000 for performing read operations in the system 1 of FIG. 1 may include the following operations. The LLC 120 may read a cache line (e.g., a 64-byte cache line) from the target memory 150 (operation 3001). The target-memory controller 130 may read data, associated with the cache line, and may read the error detection code from the target memory 150 (operation 3002). The target-memory controller 130 may check for a memory error using the error detection code (operation 3003). If an error is not detected, the target-memory controller 130 may return the data to the corresponding application (operation 3004A). If an error is detected, the target-memory controller may request the recovery code 220 (e.g., the ECC) from the secondary memory 200 (e.g., via the secondary-memory controller 140) (operation 3004B). The secondary-memory controller 140 may read the recovery code 220 from the secondary memory 200 and provide the recovery code 220 to the target-memory controller 130 (operation 3005B). The target-memory controller 130 may correct (e.g., may modify) the faulty data using the recovery code 220 and may return the corrected data to the corresponding application (operation 3006B).

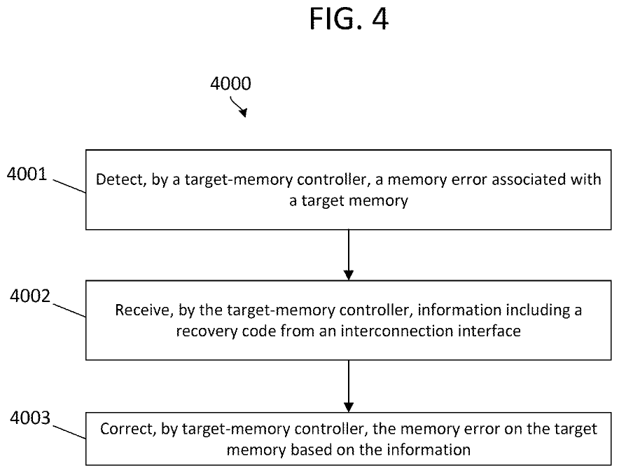

FIG. 4 is a flowchart depicting example operations of a method for memory recovery, according to some embodiments of the present disclosure.

Referring to FIG. 4, the method 4000 may include the following example operations. The target-memory controller 130 may detect a memory error associated with the target memory 150 (operation 4001). The target-memory controller 130 may receive information including a recovery code 220 from an interconnection interface 170 (operation 4002). The target-memory controller 130 may correct the memory error on the target memory 150 based on the information (operation 4003).

Accordingly, aspects of some embodiments of the present disclosure may provide improvements to computer memory by allowing for enhanced memory recovery.

Example embodiments of the disclosure may extend to the following statements, without limitation:
Statement 1. An example method includes: detecting, by a first memory controller, an error associated with a primary memory, receiving, by the first memory controller, information including a recovery code from an interface, and modifying, by the first memory controller, the error on the primary memory based on the information.
Statement 2. An example method includes the method of statement 1, wherein the interface is communicatively coupled to a secondary memory storing the recovery code.
Statement 3. An example method includes the method of any of statements 1 and 2, and further includes generating, by the first memory controller, the recovery code, and sending the recovery code to the secondary memory via the interface.
Statement 4. An example method includes the method of statement 3, wherein the sending the recovery code via the interface is in accordance with a cache-coherent protocol.
Statement 5. An example method includes the method of any of statements 1-4, and further includes storing data associated with an application in the primary memory, and storing the recovery code in the secondary memory.
Statement 6. An example method includes the method of any of statements 2-4, wherein the secondary memory is external to the primary memory.
Statement 7. An example method includes the method of any of statements 1-6, wherein the first memory controller is communicatively coupled, via a data path, to a second memory controller, and the second memory controller converts the recovery code into a format for sending from the interface.
Statement 8. An example method includes the method of any of statements 1-7, wherein the primary memory includes volatile memory.
Statement 9. An example method includes the method of any of statements 1-8, wherein the primary memory includes parity information, and the first memory controller detects the error based on the parity information.
Statement 10. An example method includes the method of any of statements 1-9, wherein the recovery code includes at least one of a single-bit error correction, double-bit error detection (SECDED) code, or a triple-bit error correction, quadruple-bit error detection (TECQED) code.
Statement 11. An example method includes the method of any of statements 1-10, wherein the primary memory includes a memory module.
Statement 12. An example method includes the method of any of statements 1-11, wherein the primary memory includes an error correction code (ECC) memory including a location for processing detection and/or correction codes, and the method further includes generating, by the first memory controller, an error detection code and writing the error detection code to the location for processing detection and/or correction codes.
Statement 13. An example method includes the method of any of statements 1-12, wherein the primary memory includes one or more volatile-memory-based chips including a parity space, and the method further includes generating, by the first memory controller, an error detection code and writing the error detection code to the parity space.
Statement 14. An example method includes the method of any of statements 1-13, wherein the first memory controller reads at least a data associated with an application and an error detection code from the primary memory.
Statement 15. An example method includes the method of any of statements 1-14, wherein the receiving the information from the interface is associated with a higher latency than receiving the information from the primary memory.
Statement 16. An example device for performing the method of any of statements 1-15 includes a primary memory, a first memory controller communicatively coupled to the primary memory, and a second memory controller.
Statement 17. An example device for performing the method of any of statements 1-15 includes an interface and a secondary memory.

While embodiments of the present disclosure have been particularly shown and described with reference to the embodiments described herein, it will be understood by those of ordinary skill in the art that various changes in form and details may be made therein without departing from the spirit and scope of the present disclosure as set forth in the following claims and their equivalents.

What is claimed is:

1. A method for memory recovery, the method comprising:
detecting, by a first memory controller, an error associated with a primary memory;
receiving, by the first memory controller, information comprising a recovery code from an interface; and
modifying, by the first memory controller, the error on the primary memory based on the information.

2. The method of claim 1, wherein the interface is communicatively coupled to a secondary memory storing the recovery code.

3. The method of claim 2, further comprising:
generating, by the first memory controller, the recovery code; and
sending the recovery code to the secondary memory via the interface.

4. The method of claim 3, wherein the sending the recovery code via the interface is in accordance with a cache-coherent protocol.

5. The method of claim 2, further comprising:
storing data associated with an application in the primary memory; and
storing the recovery code in the secondary memory.

6. The method of claim 2, wherein the secondary memory is external to the primary memory.

7. The method of claim 1, wherein:
the first memory controller is communicatively coupled, via a data path, to a second memory controller; and
the second memory controller converts the recovery code into a format for sending from the interface.

8. The method of claim 1, wherein the primary memory comprises volatile memory.

9. The method of claim 1, wherein:
the primary memory comprises parity information; and
the first memory controller detects the error based on the parity information.

10. The method of claim 1, wherein the recovery code comprises at least one of a single-bit error correction, double-bit error detection (SECDED) code, or a triple-bit error correction, quadruple-bit error detection (TECQED) code.

11. The method of claim 1, wherein the primary memory comprises a memory module.

12. The method of claim 1, wherein:
the primary memory comprises an error correction code (ECC) memory comprising a location for processing detection and/or correction codes; and
the method further comprises:
generating, by the first memory controller, an error detection code and writing the error detection code to the location for processing detection and/or correction codes.

13. The method of claim 1, wherein:
the primary memory comprises one or more volatile-memory-based chips comprising a parity space; and
the method further comprises:
generating, by the first memory controller, an error detection code and writing the error detection code to the parity space.

14. The method of claim 1, wherein the first memory controller reads at least a data associated with an application and an error detection code from the primary memory.

15. The method of claim 1, wherein the receiving the information from the interface is associated with a higher latency than receiving the information from the primary memory.

16. A device comprising:
a primary memory;
a first memory controller to generate a recovery code and communicatively coupled to the primary memory; and
a second memory controller to convert the recovery code to a format for sending from an interconnection protocol.

17. The device of claim 16, wherein the first memory controller:
receives information comprising the recovery code from the second memory controller; and
modifies an error on the primary memory based on the information.

18. The device of claim 16, wherein the primary memory comprises volatile memory.

19. The device of claim 16, wherein the primary memory comprises one or more volatile-memory-based chips comprising at least one of a parity space or a location for processing detection and/or correction codes.

20. A device comprising:
an interface to receive a request for information comprising a recovery code; and
a secondary memory comprising the recovery code and being communicatively coupled to the interface to send the recovery code from the device.
